(19) United States
(12) Patent Application Publication
(10) Pub. No.: US 2010/0321916 A1
(43) Pub. Date: Dec. 23, 2010

(54) METHOD OF CONNECTION OF FLEXIBLE PRINTED CIRCUIT BOARD AND ELECTRONIC DEVICE OBTAINED THEREBY

(76) Inventor: Yasuhiro Yoshida, Sagamihara-shi (JP)

Correspondence Address: 3M INNOVATIVE PROPERTIES COMPANY, PO BOX 33427, ST. PAUL, MN, 55133-3427, US

(21) Appl. No.: 12/865,433

(22) PCT Filed: Feb. 4, 2009
(86) PCT No.: PCT/US09/33029

§ 371 Date: Jul. 30, 2010

(30) Foreign Application Priority Data
Feb. 5, 2008 (JP) 2008-025438

(51) Int. Cl. H05K 1/14; H05K 3/36

(52) U.S. Cl. 361/803; 29/830

(57) ABSTRACT

An FPC and another circuit board having terminals parts where a plurality of conductive interconnects are arranged are prepared. An adhesive film is arranged between the terminal part of the FPC and the terminal part of the circuit board to form a stack. A rigid head having a pushing face on which a plurality of convex parts are formed is used to hot-press the stack from the FPC side to soften the adhesive film and locally expel the softened adhesive film at the locations pressed by the convex parts of the rigid head.

### TECHNICAL FIELD

The present disclosure relates to a method of connection of a flexible printed circuit board and electrical equipment. More particularly relates to a method of using hot-pressing to bond the flexible printed circuit board to another circuit board to form electrical connections.

### BACKGROUND

Digital cameras, mobile phones and other mobile devices, printers, and other electronic equipment have been made smaller and/or thinner. For electrical connection of the flexible printed circuit boards (hereinafter referred to as “FPCs”) and printed circuit boards or other circuit boards, electrical connection using adhesives instead of the conventional connector connections is often used.

As art for electrical connection of FPCs by an adhesive, anisotropic conductive film (ACF) where conductive particles contained in the resin form the electrical connections has conventionally been used. An ACF includes a resin to which conductive particles have been added which is then formed into a film shape. By stacking two terminal parts to be electrically connected with each other via a film and thermocompression bonding that stack, an electrical connection is formed between the two terminal parts via the conductive particles. However, if using an ACF for electrical connection of a circuit board with a fine interconnect width and/or interconnect pitch, a short circuit may occur between the adjoining conductive interconnects through the conductive particles. In addition, the costs of the metal included in the conductive particles (such as, e.g., silver, gold, and other precious metals) can contribute significant cost to the electrical equipment.

Therefore, nonconductive adhesive films containing substantially no conductive particles, giving equivalent electrical connection have been used in recent years. In the method of electrical connection of an FPC using nonconductive adhesive film, a stack of a FPC and other circuit board between which a nonconductive adhesive film is arranged is formed. The stack is hot-pressed to soften the nonconductive adhesive film. The softened nonconductive adhesive film is expelled from between the conductive interconnects, and the nonconductive adhesive film present at other parts is used to bond the FPC and other circuit board. The conductive interconnects of the FPC and the conductive interconnects of the other circuit board are held in the pressed state and, as a result, electrical connections are formed between these conductive interconnects. This method does not use expensive conductive particles, does not cause short-circuits even with a fine interconnect pitch, and, further, is advantageous cost-wise as well, so a great improvement in the process of production of various types of electrical equipment can be expected.

In the nonconductive film, it is necessary to expel the resin from between the conductive interconnects, so the FPC is pressed under a relatively high temperature and/or high pressure. However, use of such a high temperature and/or high pressure sometimes does not comply with the hardware specifications designed for ACFs and used in the past. Further, such processing conditions may not be cost effective due to the amount of electricity used for production, the time required for cooling, and other factors of the manufacturing process. Further, if hot-pressing FPC at a high temperature, the base film tends to elongate more. In particular, when the interconnect pitch is small, positional deviation occurs along with that elongation and poor connection may result.

Regarding the electrical connection method using a nonconductive adhesive film, Japanese Unexamined Patent Publication (A) No. 2004-221189 describes “a method of overlaying and thereby connecting corresponding conductors of a pair of flat multiconductor cables each comprised of a plurality of conductors arranged aligned in a substantially flat member, said method characterized by depositing a low melting point metal melting at a temperature lower than the conductors on the conductors in an overlay region of at least one of the pair of flat multiconductor cables, depositing a heat curing adhesive on the overlay region of at least one of the pair of flat multiconductor cables including the conductors, positioning the corresponding conductors, then thermocompression bonding the overlay regions, and bridging the corresponding conductors by the melted low melting point metal and bonding the overlay regions other than the conductors by said heat curing adhesive.” This document also describes an embodiment “giving surface relief to one of the pair of flat multiconductor cables before overlay.”

Further, Japanese Unexamined Patent Publication (A) No. 2007-5640 describes “a method of connecting circuit boards with each other comprising the steps of (i) preparing a first circuit board having a terminal of a plurality of conductive interconnects as a connecting part and a second circuit board, to be connected with said first circuit board, having a terminal of a corresponding plurality of conductive interconnects as a connecting part, (ii) arranging the connecting part of said first circuit board facing the connecting part of said second circuit board so that a heat curing adhesive film is present between the connecting part of said first circuit board and the connecting part of said second circuit board, and (iii) sufficiently pushing out the adhesive film between the facing connecting parts of the circuit boards so as to cause electrical contact and applying sufficient heat and pressure for the adhesive to cure to said connecting parts and said heat curing adhesive film, in which method the conductive interconnects forming the connecting part of at least one of said first circuit board and second circuit board include nonlinear interconnects.”

### SUMMARY

The present disclosure concerns securing sufficient reliability of electrical connection between an FPC and another circuit board. Such reliability can occur without requiring an embossing or other additional processing step on the conductive interconnects or changes in shape of the conductive interconnects or other special circuit board designs. The electrical connection can be achieved using an adhesive film, in particular a nonconductive adhesive film, at a low temperature and/or low pressure.

According to the present disclosure, there is provided a method of electrically connecting a flexible printed circuit board to another circuit board comprising the steps of preparing a flexible printed circuit board having a terminal part at which a plurality of first conductive interconnects are arranged, preparing a second circuit board having a terminal part at which a plurality of second conductive interconnects are arranged corresponding to the first conductive interconnects, positioning the terminal part of the flexible printed circuit board facing the terminal part of the second circuit board so that an adhesive film is arranged between the terminal part of the flexible printed circuit board and the terminal part of the second circuit board and forming a stack, and electrically connecting the first conductive interconnects of the flexible printed circuit board and the corresponding second conductive interconnects of the second circuit board by using a rigid head having a pressing face on which a plurality of convex parts are formed so as to hot-press the stack from the flexible printed circuit board side, soften the adhesive film and expel the softened adhesive film at the locations pressed by the convex parts of the rigid head locally from between the first conductive interconnects of the flexible printed circuit board and the corresponding second conductive interconnects of the second circuit board, bring the terminal part of the flexible printed circuit board and the terminal part of the second circuit board into local contact with each other at the locations, and bond the terminal part of the flexible printed circuit board and the terminal part of the second circuit board at parts other than the locations.

Further, according to the present disclosure, there is provided an electronic device comprising a flexible printed circuit board having a terminal part on which a plurality of first conductive interconnects are arranged, a second circuit board having a terminal part on which a plurality of second conductive interconnects corresponding to the conductive interconnects are arranged, and an adhesive film arranged between the terminal parts and bonding the two, each of the first conductive interconnects of the flexible printed circuit board and each of the corresponding second conductive interconnects of the second circuit board being locally brought into contact and electrically connected at two or more parts by thermocompression bonding using a rigid head having a pressing face on which a plurality of convex parts are formed, the two or more parts corresponding to the convex parts of the rigid head when thermocompression bonded.

According to the present disclosure, it becomes possible to electrically connect an FPC having straight conductive interconnects and another circuit board by a relatively low temperature and/or low pressure.

Note that the above-mentioned descriptions must not be deemed as disclosing all of the embodiments of the present disclosure and all of the advantages relating to the present disclosure.

### BRIEF DESCRIPTION OF THE DRAWINGS

FIG. 1 (a)-(c) schematically shows the steps of an electrical connection method according to an embodiment of the present disclosure by a cross-sectional view.

FIG. 2 is a perspective view of a rigid head having a plurality of ridges according to an embodiment of the present disclosure.

FIG. 3 is a perspective view of a rigid head having a plurality of projections arranged in an orthogonal lattice according to an embodiment of the present disclosure.

FIG. 4 shows a rigid head having a plurality of projections arranged in a zigzag state according to an embodiment of the present disclosure by a perspective view.

FIG. 5 shows the angle α formed by the long direction of the plurality of ridges with the long direction of the conductive interconnects of the FPC in one embodiment of the present disclosure having a plurality of ridges on a rigid head.

FIG. 6 shows the state of hot-pressing by an angle α of 90 degrees in an embodiment of the present disclosure having a plurality of ridges on a rigid head by a perspective view.

FIG. 7 is a cross-sectional view with the long direction of electrodes at the time of hot-pressing of FIG. 6 as the horizontal direction with respect to the paper surface.

FIG. 8 shows a cross-sectional view with the long direction of the electrodes at the time of hot-pressing of FIG. 6 as the direction vertical to the paper surface.

FIG. 9 shows the positions of electrical connection formed in an orthogonal lattice scattered state according to an embodiment of the present disclosure by a plan view.

FIG. 10 shows the positions of electrical connection formed in a zigzag lattice scattered state according to an embodiment of the present disclosure by a plan view.

FIG. 11 shows the positions of electrical connection formed by a plurality of convex parts arranged in a certain pattern according to an embodiment of the present disclosure.

FIG. 12 shows the positions of electrical connection formed by a plurality of convex parts arranged in a certain pattern according to an embodiment of the present disclosure.

FIG. 13 shows the positions of electrical connection formed by a plurality of convex parts arranged in a certain pattern according to an embodiment of the present disclosure.

FIG. 14 shows the positions of electrical connection formed by a plurality of convex parts arranged in a certain pattern according to an embodiment of the present disclosure.

FIG. 15a is a vertical cross-sectional view of a plurality of convex parts according to an embodiment of the present disclosure.

FIG. 15b is a vertical cross-sectional view of a plurality of convex parts according to an embodiment of the present disclosure.

FIG. 15c is a vertical cross-sectional view of a plurality of convex parts according to an embodiment of the present disclosure.

FIG. 15d is a vertical cross-sectional view of a plurality of convex parts according to an embodiment of the present disclosure.

### DETAILED DESCRIPTION OF THE PREFERRED EMBODIMENTS

Below, typical embodiments of the present disclosure will be explained in detail for the purpose of illustration while referring to the drawings, but the present disclosure is not limited to these embodiments.

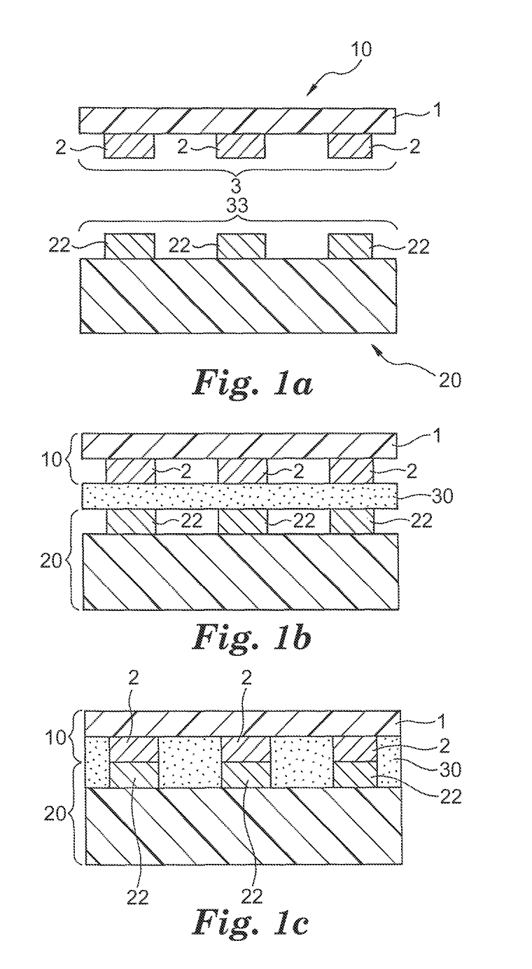

FIG. 1a to FIG. 1c schematically show the steps of the electrical connection method disclosed in the present description. First, a flexible printed circuit board (FPC) 10 and second circuit board 20 are prepared. The FPC 10 is comprised of a flexible film 1 on which first conductive interconnects 2 are arranged. The region where the first conductive interconnects 2 are arranged and where the other circuit board is to be bonded with is the terminal part 3. The second circuit board 20 has a terminal part 33 at which second conductive interconnects 22 corresponding to the first conductive interconnects 2 of FPC 10 are arranged (step (a)). Next, the terminal part 3 of the FPC 10 and the terminal part 33 of the second circuit board 20 are aligned and an adhesive film 30 is arranged between them to form a stack (step (b)). This stack is hot-pressed from the FPC side using a rigid head (not shown) having a pressing face at which a plurality of convex parts are formed so as to bond the terminal part 3 of the FPC 10 and the terminal part 33 of the second circuit board 20 and form electrical connections between the first conductive interconnects 2 of the FPC 10 and the second conductive interconnects 22 of the second circuit board 20 (step (c)). The adhesive film 30 is expelled toward the regions other than the conductive interconnects 2, 22 of the terminal parts 3, 33 (such as, e.g., in the regions between the first interconnects 2 and second interconnects 22) and the FPC 10 and the second circuit board 20 are bonded at those regions.

Note that the adhesive film may be comprised of two or more strips. The strips may be hot laminated in advance on the terminal part of the FPC or second circuit board so as to leave intervals between the strips and cut across the plurality of conductive interconnects. In this case, when hot-pressing to expel the adhesive film, the spaces between the strips are used for receiving the excess adhesive, so the adhesive can be prevented from being squeezed out from the connecting parts.

As the flexible printed circuit board (FPC), any type which includes a flexible film as a substrate and has a plurality of conductive interconnects arranged at the terminal part can be used. As the material of the flexible film, for example, polyethylene terephthalate (PET), polyimide, polyamide, and the like may be used. On these films, for example, copper, silver, nickel, gold, copper alloy, graphite paste, solder (for example Sn—Ag—Cu) is used to form conductive interconnects. In addition, for the purpose of forming good electrical connections, tin, gold, nickel, nickel/gold (two-layer plating), or another material may be imparted to the surface using electroplating or electroless plating.

In general, at the terminal part of the FPC, the plurality of conductive interconnects, whether they be the first or second interconnects, have substantially the same conductor widths and are arranged in parallel at a constant pitch. The pitch and width of the conductive interconnects can be used for typical flexible printed circuit boards. Giving one example, the pitch of the conductive interconnects may be about 20 μm to about 1 mm, while the width of the conductive interconnects may be about 10 μm to about 100 μm. As explained therein, according to an embodiment of the method of connection of the present disclosure, when the pitch of the conductive interconnects is extremely small, for example, even at the pitch of about 20 μm to about 50 μm seen in high density interconnect circuit boards, substantially no short-circuits will be caused between conductive interconnects and good electrical connections can be formed in some cases.

The second circuit board to be connected with the above-mentioned FPC may be a glass epoxy based circuit board, an aramide based circuit board, a bismaleimide triazine (BT resin) based circuit board, a glass board or ceramic board having interconnect patterns formed by ITO or fine metal particles, a silicon wafer or other rigid circuit board having metal conductor connecting parts on its surface, or a flexible circuit board including a lead type or via type FPC, or any other suitable circuit board.

In a typical circuit board, all of the conductive interconnects of the FPC correspond to all of the conductive interconnects of the second circuit board one-to-one. However, there may also be conductive interconnects of the FPC which are not connected and conversely there may also be second conductive interconnects of the second circuit board which are not connected. The conductive interconnects of the second circuit board may be formed by a material and method similar to the conductive interconnects of the FPC. In general, the pitch of the conductive interconnects of the second circuit board is substantially the same as the pitch of the conductive interconnects of the FPC, but considering the elongation of the FPC at the time of hot-pressing, the pitch of either of the conductive interconnects of the FPC or second circuit board pitch may be suitably changed. For example, the pitch of the conductive interconnects at the FPC side can be made narrower than the pitch of the conductive interconnects of the second circuit board side. Further, the width of the conductive interconnects of the second circuit board may be substantially the same as that of the conductive interconnects of the FPC, or may be suitably changed in consideration for the bonding strength between the FPC and second circuit board, the stability of the electrical connection, and the restrictions in circuit design.

The adhesive film used for connecting the FPC and second circuit board is any adhesive film softening or melting when heated to a predetermined temperature. The adhesive is expelled from between the conductive interconnects of the FPC and the conductive interconnects of the second circuit board to be connected when pressure is applied. Thus, the conductive interconnects are brought into contact at the expelled regions thereby bonding the FPC and second circuit board in the other regions.

The viscosity of the adhesive film preferably is in the range of about 500 to about 200000 Pa·s at the time of hot-pressing. Note that the “viscosity of the adhesive film” is found from the thickness (h(t)) after the time “t” (sec) when arranging an adhesive film sample of a radius “a” (m) between two horizontal plates and imparting a certain load F(N) at the measurement temperature T(° C.) and is calculated from the following formula:

h(t)/h₀=[(4h₀²Ft)/(3πηa⁴)+1]^{-1/2}

wherein, hₒ is the initial thickness (m) of the adhesive film, h(t) is the thickness (m) of the adhesive film after t seconds, F is the load (N), t is the time (sec) from which the load F is first applied, η is the viscosity (Pa·s) at the measurement temperature T° C., and “a” is the radius (m) of the adhesive film.

At the time of hot-pressing, if the viscosity is 500 Pa·s or less, the adhesive film will flow and good connections will not be able to be obtained. On the other hand, if the adhesive film has too high a viscosity, even if applying a high pressure, expelling the resin from the conductive interconnects to be connected will become difficult.

The adhesive film may also contain carbon black, copper, silver, nickel, gold, solder, gold-plated resin, gold-plated copper, or other conductive particles, but as explained above, from the viewpoint of short-circuits between conductive interconnects, manufacturing costs, it is preferable to use nonconductive adhesive film containing substantially no conductive particles. In particular, when bonding high density circuit boards with narrow conductive interconnect pitches, use of a nonconductive adhesive film is advantageous. As used herein, the term “non-conductive” refers to an insulating property possessed by an adhesive film, such that a problematic short-circuit will not occur between adjoining conductive interconnects, when an adhesive film having a given thickness is arranged between opposing conductive interconnects.

As an example of the preferably used nonconductive adhesive film, adhesive film formed from an adhesive composition comprised of a thermoplastic resin and organic particles may be used. A thermoplastic resin is a resin softening or melting when heated. The softening temperature or melt temperature is not particularly limited. A resin having an appropriate and suitable softening temperature or melting temperature in accordance with the application or required characteristics may be selected. Organic particles are particles of a material as explained herein and impart a plastic flow property to the adhesive composition, that is, impart a function by which the viscosity decreases when pressure is applied at the temperature at the time of hot-pressing. The adhesive film preferably exhibits a peel bonding strength of about 5N/cm or more when hot-pressing the circuit board to be bonded (for example, a glass epoxy board (FR-4)) at a temperature of 100 to 250° C. for 1 to 30 seconds, then performing a 90° peel test at a temperature of 25° C. and a peel rate of 60 mm/min.

The thermoplastic resin forming the adhesive film exhibiting plastic flow is not particularly limited, but may also be a base polymer generally used for a hot melt adhesive. As such a thermoplastic resin, styrenated phenol, ethylene-vinyl acetate copolymer, low density polyethylene, ethylene-acrylate copolymer, polypropylene, styrene-butadiene block copolymer, styrene-isoprene copolymer, phenoxy resin may be used. The adhesive composition preferably includes a polyester resin. This is because a polyester resin enables the adhesive composition to exhibit tackiness by heating the adhesive film for a short time.

The adhesive composition used for an adhesive film preferably includes about 25 to about 90 parts by weight of organic particles with respect to 100 parts by weight of the adhesive composition. Due to the addition of the organic particles, the resin exhibits plastic flow.

As the added organic particles, an acryl-based resin, styrene-butadiene-based resin, styrene-butadiene-acryl-based resin, melamine resin, melamine-isocyanulic acid complex, polyimide, silicone resin, polyether imide, polyether sulfone, polyester, polycarbonate, polyether ether ketone, polybenzoimidazole, polyallylate, liquid crystal polymer, olefin-based resin, ethylene-acryl copolymer, or other particles are used. That particle size is about 10 μm or less, preferably about 5 μm or less.

Further, as the adhesive film, a heat curing adhesive film including a resin which softens when heated to a predetermined temperature and cures when further heated may be used. A heat curing resin having this softening property includes both a thermoplastic ingredient and thermosetting ingredient and includes (i) a mixture of a thermoplastic resin and a thermosetting resin, (ii) a thermosetting resin modified by a thermoplastic ingredient, for example, a polycaprolactone modified epoxy resin, or (iii) a polymer resin having an epoxy group or other heat curing group in a basic structure of a thermoplastic resin, for example, a copolymer of ethylene and glycidyl (meth)acrylate.

The heat curing adhesive composition able to be particularly suitably used for such an adhesive film is a heat curing adhesive composition including a caprolactone modified epoxy resin. The caprolactone modified epoxy resin imparts suitable flexibility to the heat curing adhesive composition and can improve the viscoelastic characteristics of the heat curing adhesive. As a result, the heat curing adhesive is provided with cohesion even before curing and expresses tackiness upon heating. Further, this modified epoxy resin, like a usual epoxy resin, becomes cured with a 3-dimensional network structure upon heating and can impart cohesion to the heat curing adhesive.

When using a caprolactone modified epoxy resin as a heat curing resin, the heat curing adhesive composition may further include a phenoxy resin or other thermoplastic resin for improving the repairability. The “repairability” means the ability for the adhesive film to be peeled off and reestablish connection by heating to for example 120° C. to 200° C. after the connection step. Furthermore, for example, in accordance with demands for improvement of the heat resistance, the heat curing adhesive composition may further contain, in combination with the above-mentioned phenoxy resin or independent from it, a second epoxy resin. This epoxy resin may be, for example, a bisphenol A type epoxy resin, a bisphenol F type epoxy resin, a bisphenol A diglycidyl ether type epoxy resin, and a phenol novolac type epoxy resin.

Further, in order to cause a curing reaction of the epoxy resin, a curing agent may optionally be added to the heat curing adhesive composition. As the curing agent, for example, an amine curing agent, acid anhydride, dicyan diamide, cationic polymerization catalyst, imidazole compound, hydrazine compound may be mentioned.

Furthermore, the heat curing adhesive composition may contain, with respect to 100 parts by weight of the adhesive composition, about 15 to about 100 parts by weight of the above-mentioned organic particles. Due to the addition of the organic particles, the resin exhibits plastic flow, while the organic particles maintain the flexibility of the heat curing adhesive composition after curing.

The terminal part of the FPC and the terminal part of the second circuit board may be aligned by a method generally used for electrical connection of an FPC. As an example, aligning utilizing image recognition by a microscope of the conductive interconnects of the terminal parts themselves or alignment marks made at parts other than the conductive interconnects of the terminal parts may be mentioned. The adhesive film arranged between the terminal part of the FPC and the terminal part of the second circuit board may be attached in advance to the terminal part of either the FPC or second circuit board. At the time of the alignment, it may also be arranged between the FPC and second circuit board. In this way, a stack is formed by the terminal part of the FPC and the terminal part of the second circuit board between which an adhesive film is arranged.

The hot-pressing may be performed by a ceramic heat bonder enabling pressing and pulse like heating or another bonder called a “pulse heat bonder.” For example, a thermocompression bonder made by Avionics Japan Inc. (Product No.: TCW-125B) may be used.

The head of the bonder includes a heater. At the time of hot-pressing, the temperature of the head can be raised. The head has a pressing face at which a plurality of convex parts are formed. The pressing face at which the plurality of convex parts are formed may be formed integrally with the head. It is also possible to use another member provided with a plurality of convex parts as the pressing face and separately attach it to a head provided with a heater. In the latter case, between the other member provided with the plurality of convex parts used as the pressing face and the head, for example an additional member for fixing them may be interposed. The material forming the pressing face having a plurality of convex parts is comprised of a hard material from the viewpoint of efficiently expelling the adhesive film from between the conductive interconnects to be connected. For example, it is preferably comprised of ceramic having sufficient heat resistance at the usage temperature, stainless steel, copper, or another metal. Further, the head may also be made by a hard material for similar reasons. The material explained above for the material forming the pressing face having a plurality of convex parts is preferable. Further, the material forming the pressing face having a plurality of convex parts and the material of the head may be the same or different. When the pressing face having a plurality of convex parts is formed integral with the head, generally they are the same in material. Further, when using an additional member, the material is preferably the material explained above for the material of the head and the material forming the pressing face.

The plurality of convex parts are designed to reduce the actual contact area with the FPC compared with the area of the head and thereby raise the effective pressure at the time of hot-pressing and/or lower the temperature at the time of hot-pressing. For that reason, by using a rigid head having a plurality of convex parts at a pressing face, it is possible to locally expel the adhesive film softened at locations pressed by the convex parts of the rigid head from between conductive interconnects to be connected under general hot-pressing conditions or conditions gentler than that and bringing the FPC and second circuit board into local contact with each other at those locations and thereby form electrical connections between the boards. Further, at the time of hot-pressing, at the regions between the convex parts, the pressure applied to the FPC is relatively low. As a result, space for the flow of the softened adhesive film may be formed between the FPC and second circuit board, so compared with when using a flat head for hot-pressing, the softened film can be easily expelled from between the conductive interconnects to be connected.

The convex parts may be arranged regularly or irregularly so long as pushing these plurality of convex parts against the FPC results in all of the conductive interconnects of the FPC being electrically connected with the conductive interconnects of the second circuit board. For example, when two types of terminal parts with different widths and/or pitches of the conductive interconnects, for example, a terminal part for signal use and a terminal part for power supply, adjoin each other and simultaneously connecting these terminal parts, it is also possible to change the contact areas and/or intervals or pitches of the plurality of convex parts at the parts corresponding to each of the terminal parts. For example, as explained later, when the plurality of convex parts is a plurality of ridges, the pitch and/or width of the ridges may be changed in the extending direction of the ridges or may be changed between any two adjoining ridges. These plurality of convex part are preferably arranged so as to contact the FPC at two or more positions per conductive interconnect with regard to all of the conductive interconnects of the FPC to be electrically connected at the time of hot-pressing. By arranging the plurality of convex parts to contact the FPC at two or more positions per conductive interconnect, the conductive interconnects of the FPC are electrically connected with the corresponding conductive interconnects of the second circuit board at two or more parts. For this reason, for any conductive interconnect, even if defective electrical connection occurs during manufacture or in use after manufacture, the required conduction can be secured by the remaining electrically connected parts. Therefore, designing the arrangement of the convex parts in this way contributes to the improvement of the reliability of the electrical connections obtained by the method of the present disclosure.

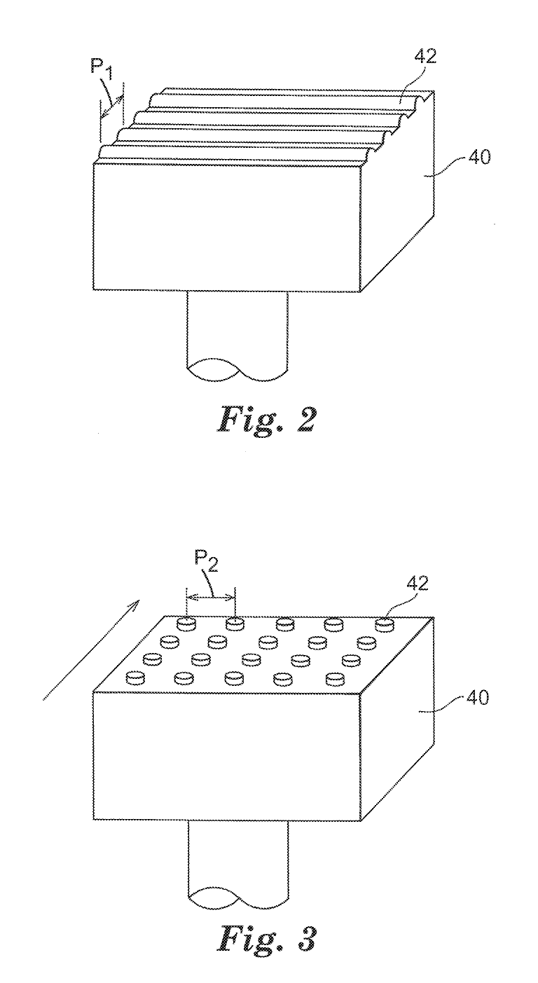

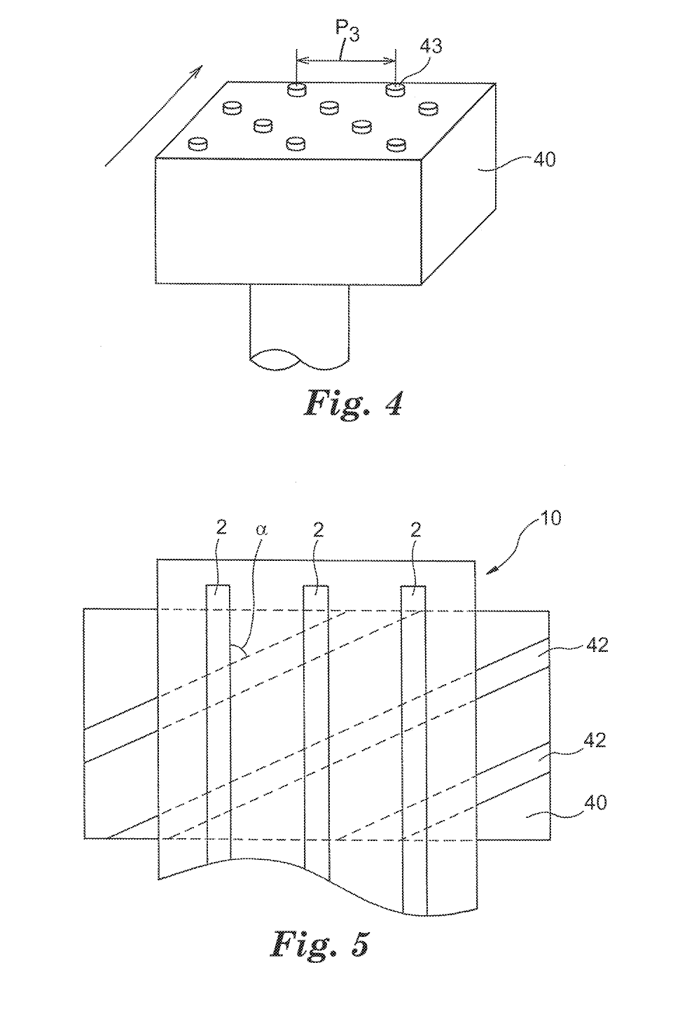

FIGS. 2 to 4 show several embodiments of regular arrangements of the convex parts 41 with the pressing face of the rigid head 40 upward by a perspective view. In FIG. 2, the plurality of ridges 42 with constant widths are arranged at a constant pitch P₁ in parallel to the pressing face of the rigid head 40. In this figure, the vertical cross-section of the ridges is shown as being semicircular. In FIG. 3, the plurality of projections 43 are arranged in an orthogonal state based on the long direction of the conductive interconnects of the FPC shown by the arrows in the figure. In this figure, the projections are shown as columnar and are arranged in a direction perpendicular to the long direction of the conductive interconnects of the FPC at a pitch P₂. In FIG. 4, the plurality of projections 44 are arranged in a zigzag state based on the long direction of the conductor interconnects of the FPC shown by the arrows in the figure. In this figure, the projections are shown as columnar and are arranged in a direction perpendicular to the long direction of the conductive interconnects of the FPC at a pitch P₃.

In an embodiment where the plurality of convex parts are a plurality of ridges, at the time of hot-bonding, the angle α formed by the long direction of the plurality of ridges with the long direction of the conductive interconnects of the FPC may be any angle. FIG. 5 schematically shows this state. In FIG. 5, to facilitate understanding of the positional relationship between the plurality of ridges 42 formed on the pressing face of the rigid head 40 and the conductive interconnects 2 of the FPC 10, the second circuit board and adhesive are omitted and a plan view seen from the plane of arrangement of the conductive interconnects of the FPC is shown. Further, here, the width and pitch of the conductive interconnects and the width and pitch of the ridges are drawn exaggeratedly for illustrative purposes. The present disclosure is not limited to these dimensions and ratio. What is shown in the figure is the angle α formed by the long direction of the plurality of ridges and the long direction of the conductive interconnects of the FPC. This means that the plurality of ridges are pushed against the FPC at positions corresponding to the conductive interconnects of the FPC as a whole, whereby the conductive interconnects are electrically connected. Further, if the angle α is for example 90 degrees, this means that the conductive interconnects are electrically connected at positions where the plurality of ridges and the conductive interconnects of the FPC perpendicularly intersect when the plurality of ridges are pushed against the FPC.

It is preferable to use the plurality of ridges with said angle α larger than 0 degree, for example, 45 degrees, 60 degrees 90 degrees, or another angle so as to electrically connect the conductive interconnects of the FPC with the corresponding conductive interconnects of the second circuit board at two or more parts. By electrically connected them in this state, as explained above, it is possible to improve the reliability of the electrical connections.

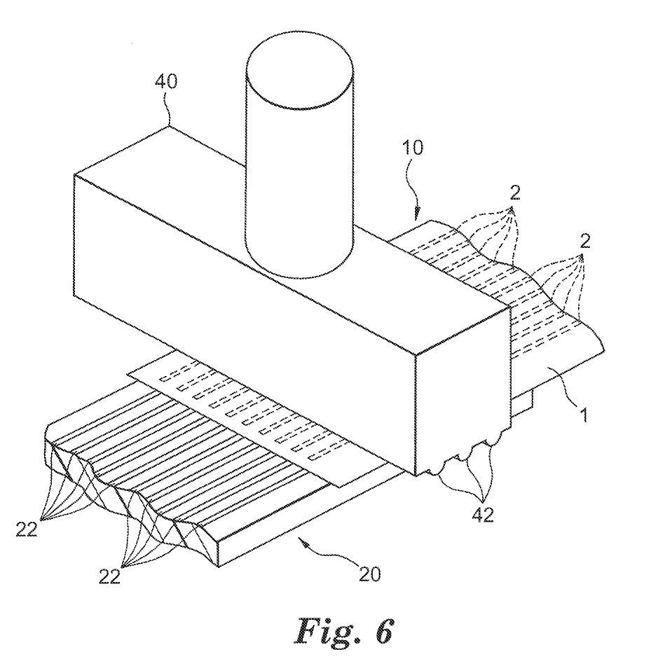

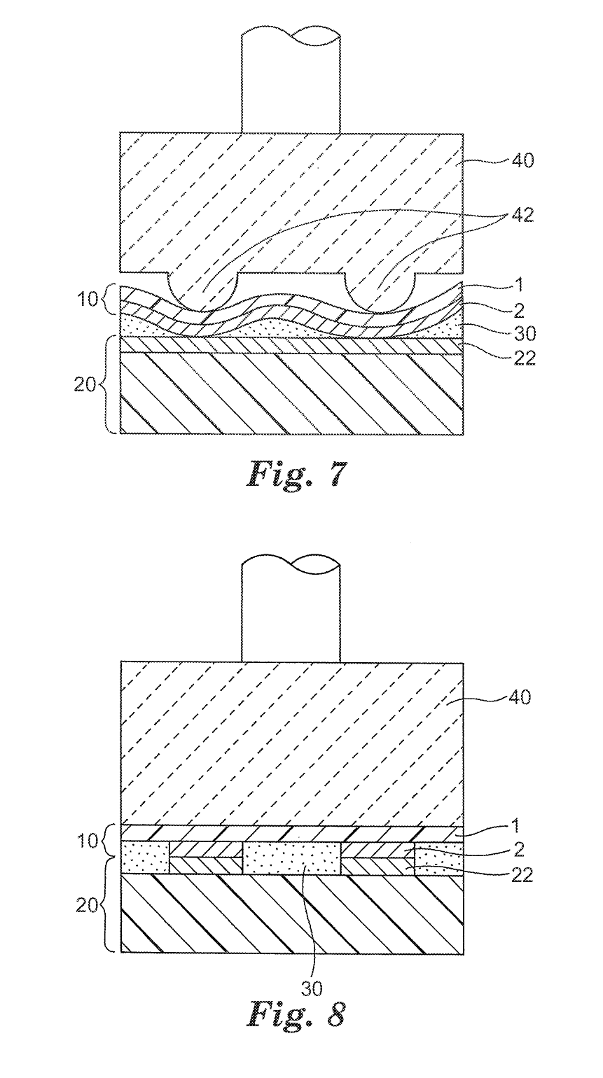

The angle α may be made any angle, but if the angle α becomes larger to a certain extent, alignment of the ridges and conductive interconnects becomes unnecessary. Further, the larger the angle α, the greater the number of connection points obtained by a head of the same ridge pitch, so the angle α is preferably larger. The angle α is more preferably made about 90 degrees. The state where the angle α is made 90 degrees and the FPC and second circuit board are hot-pressed is shown by a simple perspective view in FIG. 6. This figure shows an embodiment hot-pressing a stack of the FPC 10 and second circuit board 20 via an adhesive film in the state with the ridges 42 of the rigid head 40 perpendicularly intersecting the conductive interconnects 2 of the FPC 10 and the conductive interconnects 22 of the second circuit board 20. In this figure, the pitch of the ridges 42 is drawn larger than the pitch of the conductive interconnects 2, 22. Furthermore, cross-sectional views of the long direction of the electrode in the horizontal direction and vertical direction with respect to the paper surface for the stack hot-pressed and thermocompression bonded in this way are shown in FIG. 7 and FIG. 8. In FIG. 7, the state is schematically shown where the plurality of ridges 42 contact the FPC 10, whereby the flexible film 1 and the conductive interconnects 2 bend somewhat, the FPC 10 is bonded with the second circuit board 20, and electrical connections are formed between the conductive interconnects 2 and 22. FIG. 8 schematically shows the state where the softened film is expelled to the regions other than the conductive interconnects 2, 22. Note that in FIG. 7 and FIG. 8, an embodiment of ceramic with the rigid head 40 and ridges 42 formed integrally is shown, but the shapes and materials of the rigid head and convex parts are not limited to these drawings. Unless otherwise alluded to, the same applies to the following drawings illustrating the rigid head and convex parts. In the embodiment illustrated in FIGS. 6 to 8, the ridges 42 are integral with the rigid head 40, so in FIG. 8, the ridges 42 are not shown, but substantially correspond to the bottom of the rigid head 40. As will be understood from FIG. 7 and FIG. 8, in this embodiment, in addition to the spaces between the adjoining conductive interconnects 2, 22 on the FPC 10 (in FIG. 8, the regions where the adhesive film 30 is present), spaces for flow of the softened film (in FIG. 7, the regions where the adhesive film 30 is present) are formed in the corresponding regions between the ridges 42. For this reason, the degree of freedom of the direction of flow of the softened film is increased and the softened film can pass through shorter paths and be expelled from the connecting parts of the conductive interconnects. As a result, even when hot-pressing at a low temperature and/or low pressure, sufficient electrical connections can be formed.

In the embodiment hot-pressing by an angle α of 0 degree, the pitch of the plurality of ridges is made the same as or ½, ⅓, or another multiple of a reciprocal of an integer of the pitch of the FPC conductive interconnects. By setting the pitches of the ridges in this way and suitably aligning the head at the time of hot-pressing, all conductive interconnects are electrically connected. On the other hand, in an embodiment where the angle α is made an angle of other than 0 degree, the pitch of the plurality of ridges does not have to be made the same or smaller than the pitch of the conductive interconnects. More specifically, in an embodiment where the angle α is made an angle of other than 0 degree, if an angle where two adjoining ridges among a plurality of ridges cross a one conductor of the terminal part, as explained above, the conductive interconnects of the FPC and the corresponding conductive interconnects of the second circuit board can be electrically connected at two or more parts. Therefore, in the case of this embodiment, so long as satisfying the above condition relating to the angle, the pitch of the plurality of ridges can be set regardless of the pitch of the conductive interconnects. For example, even if trying to connect a high density circuit board having an extremely narrow pitch of conductive interconnects, for example, when the angle α is 90 degrees, it is possible to use a head with a relatively large pitch of the ridges on the condition that the pitch of the ridges is smaller than the length of the terminal part of the FPC. Because this enables the problem of the processing precision required when forming ridges on a rigid head to be eased, procurement of the head becomes easier. As a result, electrical connection of the high density circuit board can be performed simpler and less expensively.

Further, the larger the pitch of the ridges, the larger the space in the region corresponding to between the ridges where the resin (nonconductive adhesive film) expelled from between the conductive interconnects to be connected flows into and the easier the connection at a low temperature and/or low pressure. Therefore, the pitch of the plurality of ridges based on the long direction of the conductive interconnects of the FPC is preferably the same as or larger than the pitch of the conductive interconnects of the FPC. Two times or more the conductive interconnect pitch of the FPC is more preferable, while four times or more the conductive interconnect pitch of the FPC is still more preferable. On the other hand, if the pitch of the plurality of ridges is too large, the number of locations of contact per conductive interconnect becomes smaller, so the pitch of the plurality of ridges is preferably shorter than the length of the terminal parts. One-half or less the length of the terminal parts is more preferable, one-quarter or less is still more preferable.

Further, if all of the conductive interconnects are to be connected, the plurality of ridges do not need to be continuous in their extending direction and may be divided into a plurality of sections having any lengths.

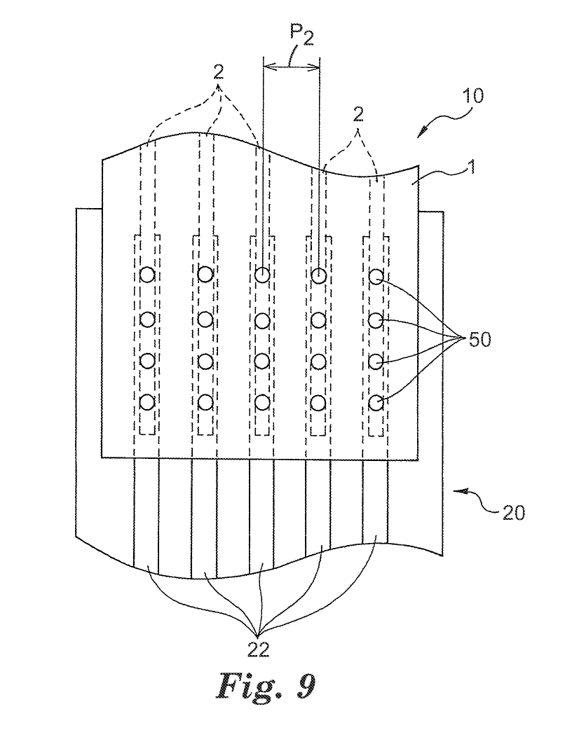

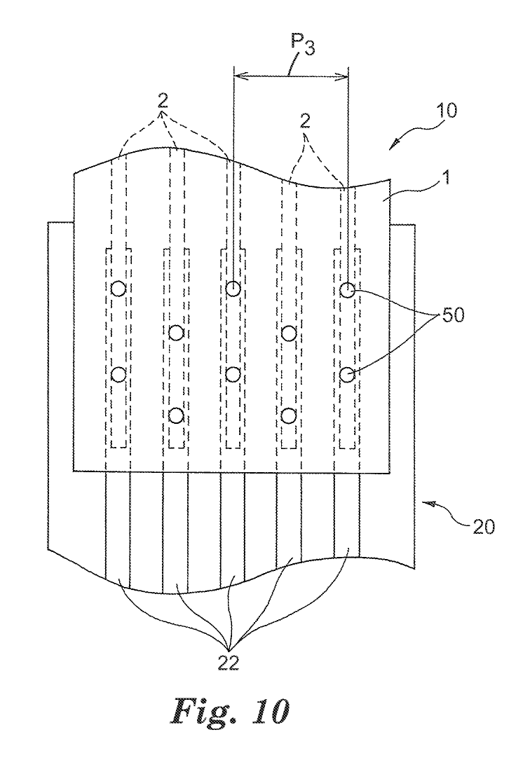

In another embodiment, the plurality of convex parts may be made a plurality of projections arranged in an orthogonal lattice state or zigzag state. In that embodiment, the contact faces of the plurality of projections may be circular, square, or any other shapes. Further, the plurality of projections may contact the FPC at the time of hot-pressing in a manner deemed as point contact or line contact. The pitch (P₂, P₃) of the plurality of projections relating to the direction perpendicularly intersecting the long direction of the conductive interconnects of the FPC, that is, the pitch direction of the conductive interconnects, is generally set to be the same as the pitch of the conductive interconnects in the case of a plurality of projections arranged in an orthogonal lattice state (P₂) and is set to become two times the pitch of the conductive interconnects in the case of a plurality of projections arranged in a zigzag state (P₃). However, as explained above in an embodiment hot-pressing by an angle α of 0 degree, the pitch P₂ or P₃ of the plurality of projections may be made ½, ⅓, or another multiple of a reciprocal of an integer of the pitch of the conductive interconnects of the FPC. If using a rigid head having a plurality of projections arranged in an orthogonal lattice state or zigzag state in this way for hot-pressing, electrical connections can be formed between the conductive interconnects in an orthogonal lattice scattered state or zigzag lattice scattered state at positions on the conductive interconnects of FPC and a plurality of lines crossing the long direction of the conductive interconnects. That state is shown in FIG. 9 and FIG. 10. The parts where the electrical connections are formed are shown surrounded by the circle marks 50.

In particular, if forming the electrical connections scattered in a zigzag lattice, since the hot-pressed points or parts are arranged alternately with respect to adjoining conductive interconnects, at the time of hot-pressing, the elongation of the flexible film of the FPC is cancelled out on the order of the pitch of the conductive interconnects, and the stability of the electrical connections and bonding strength can be expected to be improved. Further, if using a plurality of projections arranged in a zigzag state, a large space can be secured between two adjoining projections in the direction perpendicular to the long direction of the conductive interconnects, that is, the pitch direction of the above-mentioned conductive interconnects, so the space through which the expelled resin (adhesive film) can flow out becomes wider compared with an orthogonal lattice state arrangement.

In another embodiment arranging the plurality of projections in a zigzag state, regarding the pitch direction of the conductive interconnects, by making the projection pitch P₃ smaller than two times the projection width W (P₃<2×W), even without precise positioning of the conductive interconnects and the projections, the projections can press against all of the conductive interconnects at a certain part or a plurality of parts. Therefore, in this embodiment, when desiring to make the projection width smaller, the projection pitch may be made smaller.

Further, the projection pitch in the pitch direction of the conductive interconnects is preferably made larger than the width of the narrow conductor interconnects among two facing conductive interconnects to be connected. If doing this, two or more projections will never be arranged aligned on a single conductive interconnect along the pitch direction of the conductive interconnects. As a result, either direction of the pitch direction of the conductive interconnects can become the flow path of the resin to be expelled, so this is more advantageous for expelling the resin from between the conductive interconnects to be connected.

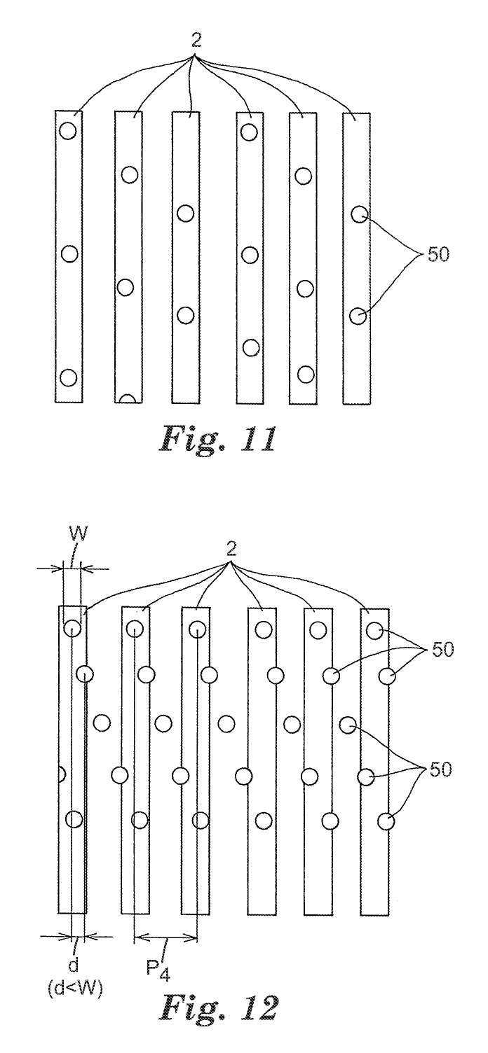

As above-mentioned, the arrangement of the plurality of convex parts was explained for a plurality of ridges and projections arranged in an orthogonal lattice state or zigzag state, but the arrangement of the plurality of convex parts is not limited to them. For example, as shown in FIG. 11, the plurality of convex parts may also be arranged in a regular pattern of a group of a plurality of conductive interconnects. In FIG. 11 and the following shown FIGS. 12 to 14, for simplification of the explanation, only the electrical connection parts 50 formed by six FPC side conductive interconnects 2 and the arranged convex parts are schematically shown.

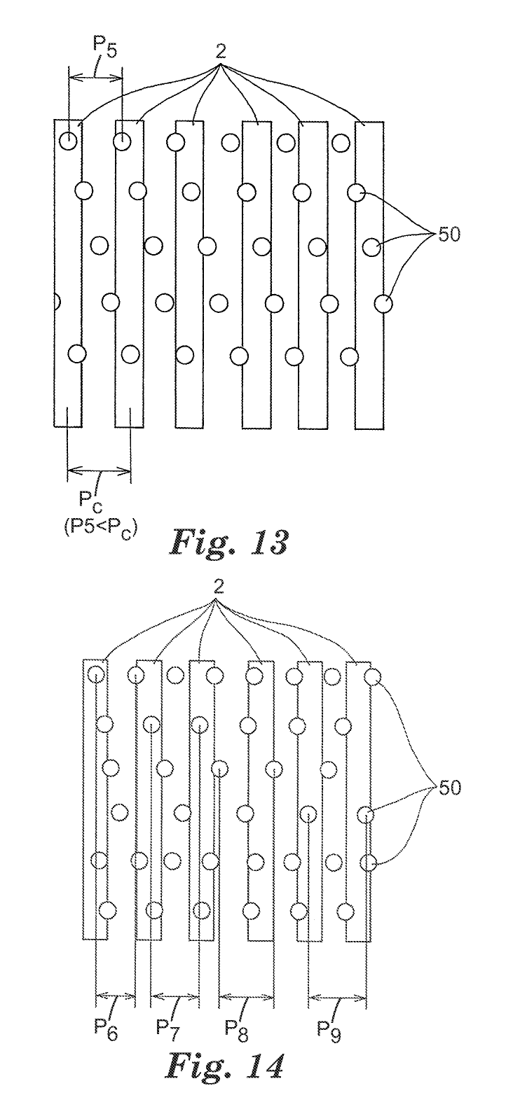

Even a random or regular arrangement where there are two or more convex parts in the long direction of the conductive interconnects at any position may be advantageous in that precise alignment of the conductive interconnects and convex parts is not necessary for some cases, as described for the zigzag state arrangement. For example, as shown in FIG. 12, by providing a plurality of lines each comprised of a plurality of convex parts arranged at a pitch (P₄) the same as the conductive interconnect pitch along the pitch direction of the conductive interconnects and arranging these lines offset from each other in the pitch direction of the conductive interconnects by exactly the length d smaller than the width W of the convex parts (d<W) relating to the pitch direction of the conductive interconnects, it is possible to enjoy the above-mentioned advantage of simpler alignment. Further, as shown in FIG. 13, even if the pitch P₅ of the plurality of convex parts is shorter than the pitch P_{c} of the conductive interconnects (P₅<P_{c}), even if the pitch of the plurality of convex parts is longer than the pitch of the conductive interconnects (not shown), similar advantages can be enjoyed. As a further embodiment, for example, as shown in FIG. 14, an arrangement where the pitches of the plurality of lines of convex parts are made different (P₆ to P₉) and the convex parts of all of the lines in the pressed regions are arranged so as never to be aligned in the long direction of the conductive interconnects may be mentioned.

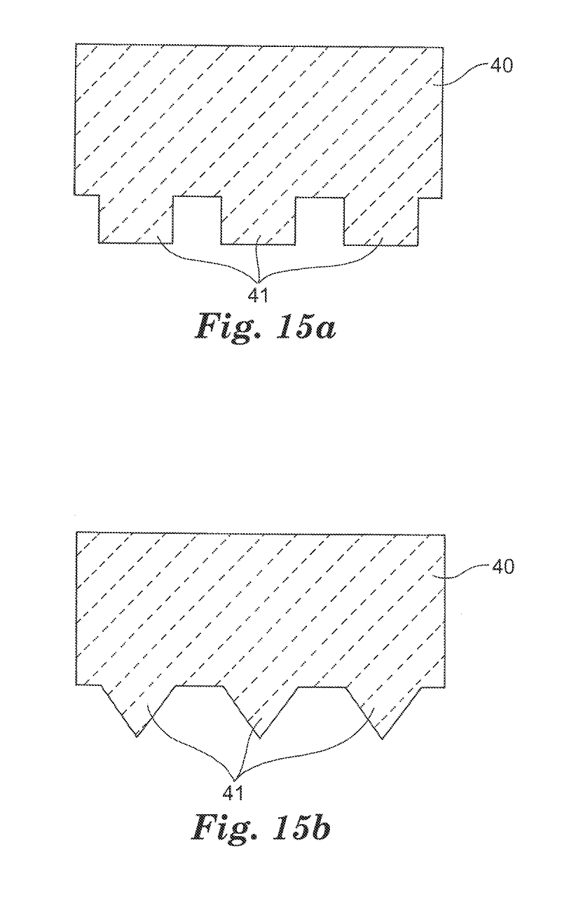

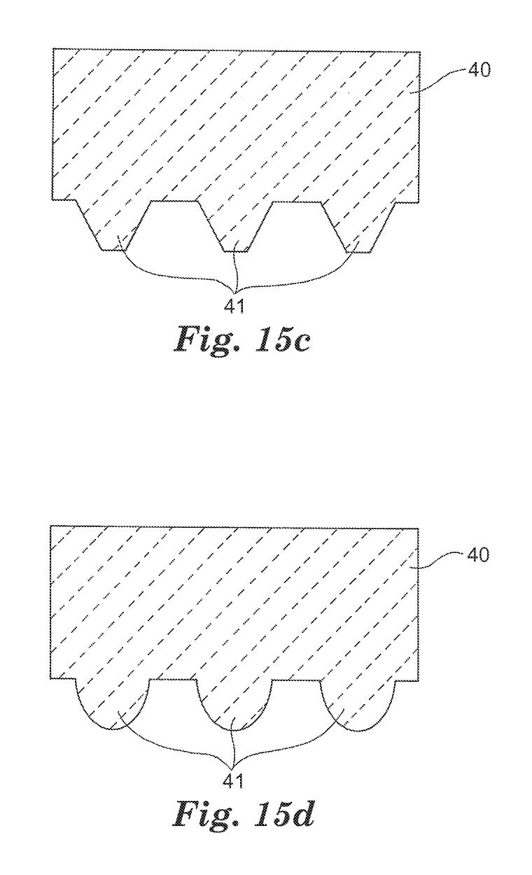

As shown in FIGS. 15a to d as examples, at least one vertical cross-section of the plurality of convex parts may be a block shape (FIG. 15a), conical shape (FIG. 15b), frustoconical shape (FIG. 15c), part of a circle (FIG. 15d), or a combination of the same. Here, the “at least one vertical cross-section of the plurality of convex parts” means the cross-section when cutting the plurality of convex parts at least at one plane including the axis of the head in the pressing direction. From the viewpoint of processing of the rigid head, forming the vertical cross-section into a block shape is generally simple. On the other hand, by for example making the vertical cross-section a conical shape, frustoconical shape, or semicircular shape, the pressure at the parts where the convex parts contact the FPC can be increased, and then the softened adhesive film can be expelled from between the conductive interconnects and easily made to flow to other regions. For similar reasons, the block shaped or frustoconical shaped contact areas are preferably made projecting curved surfaces.

The temperature and pressure at hot-pressing are determined by the resin composition of the adhesive film selected. They are not particularly limited, but the pressure can be made about 1 to 4 MPa and the temperature can be made about 70° C. to 170° C. If in this range of temperature and pressure, it is possible to suitably utilize a generally commercially available heat bonder. Further, according to the method of the present disclosure, compared with the conventional method of hot-pressing using a flat head, even if using a thicker adhesive film, it is possible to maintain equivalent electrical connections under equivalent temperature and pressure conditions, so in applications where a high bonding strength is required, it is also possible to use a thicker adhesive film under conditions of a relatively high temperature and/or high pressure. Note that when using a heat curing adhesive film, after hot-pressing, the film may be post cured at for example about 150° C. to about 250° C.

By using the above-mentioned connection method, it is possible to produce various electronic devices containing FPCs and circuit boards where the conductive interconnects of the flexible printed circuit board and the corresponding conductive interconnects of the second circuit board are locally thermocompression bonded at two or more parts and electrically connected and where the electrical connection has sufficient reliability, for example, plasma displays, liquid crystal displays, or other flat panel displays, organic EL displays, notebook computers, mobile phones, digital cameras, digital video cameras, or other electronic equipment.

### EXAMPLES

Below, a typical example will be explained in detail, but it is clear to persons skilled in the art that the example can be modified and changed in the scope of the claims of the present application.

In the example, to keep the workload in the processing of the rigid head to a minimum and prove the present disclosure, a pressing face having a plurality of convex parts was fabricated by aligning and fixing 10 copper wires with circular cross-sections (φ0.18) at a pitch of about 0.4 mm on a polyimide tape, making the copper wires face the outside so as to contact the FPC, and fixing the pressing face with the entire polyamide tape to a flat head. In this case, the ridges are circular in vertical cross-section, but the parts substantively contacting the FPC may be considered the bottom halves of circles. Next, a nonconductive adhesive film of a width 2 mm×length 18.5 mm (brand name REX7132, Sumitomo 3M) was bonded at 120° C. and 2 MPa for 4 seconds to temporarily fix it to an FPC provided with 51 conductive interconnects (nickel/gold plating) of a conductive interconnect pitch of 0.2 mm, a conductor width of 50 μm, and a conductor thickness of 18 μm on a terminal part of a 25 μm thick polyamide film. After that, a glass epoxy board provided at the terminal part with the same dimensions of, the same material of, and the same number of conductive interconnects of conductive interconnects of the FPC was stacked over the nonconductive adhesive film. This stack was hot-pressed by a heat bonder set to a temperature of 170° C. and a pressure of 4 MPa for 5 seconds to form electrical connections between the conductive interconnects of the FPC and glass epoxy board.

Further, as a comparative example, except for embossing the surface of the conductive interconnects of the FPC to form surface relief and, at the time of hot-pressing, using a head with a flat pressing face, the same procedure was used to hot-press a stack and form electrical connections between the conductive interconnects of the FPC and glass epoxy board. The embossing was formed across lengths of 2.4 mm of the conductors along the long direction of the conductive interconnects so that the embossed heights of the conductive interconnects became about 5 μm.

The initial conductance (for total of 51 conductive interconnects, including conductor resistance) was measured, whereupon it was above the measurement limit for the FPC/glass epoxy board of the comparative example (10Ω or more) and could not be measured, while was a maximum of 3.718Ω for the FPC/glass epoxy board of the example.

Further, the FPC/glass epoxy board of the example was subjected to a reliability test at a temperature of 85° C. and a relative humidity of 85% for 500 hours, whereupon the increase in the resistance after the elapse of 500 hours was just about 30 mΩ.

1. A method of electrically connecting a flexible printed circuit board to another circuit board comprising the steps of
preparing a flexible printed circuit board having a terminal part at which a plurality of first conductive interconnects are arranged,
preparing a second circuit board having a terminal part at which a plurality of second conductive interconnects are arranged corresponding to said first conductive interconnects,
aligning the terminal part of said flexible printed circuit board facing the terminal part of said second circuit board so that an adhesive film is arranged between the terminal part of said flexible printed circuit board and the terminal part of said second circuit board and forming a stack, and
electrically connecting the first conductive interconnects of said flexible printed circuit board and the corresponding second conductive interconnects of said second circuit board by using a rigid head having a pressing face on which a plurality of convex parts are formed so as to hot-press said stack from said flexible printed circuit board side, soften said adhesive film and expel the softened adhesive film at the locations pressed by the convex parts of said rigid head locally from between the first conductive interconnects of said flexible printed circuit board and the corresponding second conductive interconnects of said second circuit board, bring the terminal part of said flexible printed circuit board and the terminal part of said second circuit board into local contact with each other at said locations, and bond the terminal part of said flexible printed circuit board and the terminal part of said second circuit board at parts other than said locations.

2. A method of claim 1, wherein said adhesive film is a nonconductive adhesive film.

3. A method of claim 1, wherein each of the first conductive interconnects of said flexible printed circuit board are electrically connected to each of the corresponding second conductive interconnects of said second circuit board at two or more parts.

4. A method of claim 3, wherein the plurality of convex parts of the pressing face of said rigid head are a plurality of ridges and said plurality of ridges electrically connect each of the first conductive interconnects of said flexible printed circuit board to each of the corresponding second conductive interconnects of said second circuit board at two or more parts.

5. A method of claim 4, wherein a pitch of said plurality of ridges based on the long direction of the first conductive interconnects of said flexible printed circuit board is larger than a pitch of the first conductive interconnects of said flexible printed circuit board.

6. A method of claim 3, wherein a rigid head having a plurality of convex parts arranged in an orthogonal lattice state on the pressing face is used to electrically connect the first conductive interconnects of said flexible printed circuit board and the corresponding second conductive interconnects of said second circuit board in an orthogonal lattice scattered state at positions on the first conductive interconnects of said flexible printed circuit board and on a plurality of lines crossing the long direction of said first conductive interconnects.

7. A method of claim 3, wherein a rigid head having a plurality of convex parts arranged in a zigzag state on the pressing face is used to electrically connect the first conductive interconnects of said flexible printed circuit board and the corresponding second conductive interconnects of said second circuit board in a zigzag lattice scattered state at positions on the first conductive interconnects of said flexible printed circuit board and on a plurality of lines crossing the long direction of said first conductive interconnects.

8. A method of claim 1, wherein at least one vertical cross-section of the plurality of convex parts formed on the pressing face of said rigid head is a block shape, conical shape, frustoconical shape, or part of a circular shape or a combination thereof.

9. A method of claim 1, wherein the material forming the pressing face of said rigid head is ceramic, stainless steel, or copper.

10. A method of claim 1, wherein said hot-pressing is performed at a pressure of 1 MPa to 4 MPa and a temperature of 70° C. to 170° C.

11. A method of claim 1, wherein the pitch of the first conductive interconnects of the terminal part of said flexible printed circuit board is 20 μm to 1 mm and the width of the first conductive interconnects is 10 μm to 100 μm.

12. A method of claim 1, wherein said adhesive film includes a thermoplastic resin and exhibits plastic flow.

13. An electronic device comprising a flexible printed circuit board having a terminal part on which a plurality of first conductive interconnects are arranged, a second circuit board having a terminal part on which a plurality of second conductive interconnects corresponding to said first conductive interconnects are arranged, and an adhesive film arranged between the terminal parts and bonding the two, each of the first conductive interconnects of said flexible printed circuit board and each of the corresponding second conductive interconnects of said second circuit board being brought locally into contact and electrically connected at two or more parts by thermocompression bonding using a rigid head having a pressing face on which a plurality of convex parts are formed, the two or more parts corresponding to the convex parts of the rigid head when thermocompression bonded.

14. Electronic equipment of claim 13, wherein the first conductive interconnects of said flexible printed circuit board and the corresponding second conductive interconnects of said second circuit board are electrically connected in an orthogonal lattice scattered state at positions on the first conductive interconnects of said flexible printed circuit board and on a plurality of lines crossing the long direction of said first conductive interconnects.

15. Electronic equipment of claim 13, wherein the first conductive interconnects of said flexible printed circuit board and the corresponding second conductive interconnects of said second circuit board are electrically connected in a zigzag lattice scattered state at positions on the first conductive interconnects of said flexible printed circuit board and on a plurality of lines crossing the long direction of said first conductive interconnects.
